(19) United States
(12) Patent Application Publication
(10) Pub. No.: US 2025/0359093 A1
(43) Pub. Date: Nov. 20, 2025

(54) UNIT CELL FOR METAL FILL

(71) Applicant: Cisco Technology, Inc., San Jose, CA (US)

(72) Inventors: Hailing WANG, Acton, MA (US); Brandon T. DUSEK, Austin, TX (US); Latha SATHAPPAN, San Jose, CA (US); Arian Joy S. VELARDE, Fremont, CA (US); Mark C. NOWELL, Ottawa (CA); Manjing XIE, Los Gatos, CA (US)

(21) Appl. No.: 18/669,461

(22) Filed: May 20, 2024

(51) Int. Cl. H10D 1/68

(52) U.S. Cl. CPC H10D 1/714

(57) ABSTRACT

The present disclosure describes an integrated circuit that uses a unit cell of capacitors as floating metal fill. An integrated circuit includes a first capacitor that includes a transistor and a second capacitor that includes a first set of metal fingers and a second set of metal fingers. The transistor is positioned in a first layer of the integrated circuit and a second layer of the integrated circuit. The transistor forms an anode and a cathode of the first capacitor. The first set of metal fingers are interdigitated with the second set of metal fingers. The first set of metal fingers and the second set of metal fingers are positioned in the second layer. The first set of metal fingers are electrically connected to the cathode of the first capacitor. The second set of metal fingers are electrically connected to the anode of the first capacitor.

### TECHNICAL FIELD

Embodiments presented in this disclosure generally relate to integrated circuits. More specifically, embodiments disclosed herein a unit cell for metal fills in integrated circuits.

### BACKGROUND

Existing integrated circuits (e.g., photonic integrated circuits and electronic integrated circuits) include decoupling capacitors that filter out noises at different frequencies. These capacitors may occupy large areas in the integrated circuits. Additionally, the integrated circuits may include electrically floating metal fills (which may be referred to as dummy metal fills) to satisfy density requirements for reliability and manufacturability purposes. These metal fills occupy additional areas in the integrated circuits but provide little or no functionality. As a result, the metal fills may increase die size and cost and are an inefficient use of the area of the integrated circuits.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 illustrates an example system.

FIG. 2 illustrates an example unit cell in the system of FIG. 1.

FIG. 3 illustrates an example capacitor in the unit cell of FIG. 2.

FIGS. 4A and 4B illustrate an example capacitor in the unit cell of FIG. 2.

FIG. 5 illustrates an example capacitor in the unit cell of FIG. 2.

FIGS. 6A through 6F illustrate an example unit cell in the system of FIG. 1.

FIGS. 7A through 7F illustrate example arrangements of unit cells in the system of FIG. 1.

FIG. 8 illustrates portions of the system of FIG. 1.

FIG. 9 is a flowchart of an example method performed by the system of FIG. 1.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

The present disclosure describes an integrated circuit that uses a unit cell of capacitors as floating metal fill. According to an embodiment, an integrated circuit includes a first capacitor that includes a transistor and a second capacitor that includes a first set of metal fingers and a second set of metal fingers. The transistor is positioned in a first layer of the integrated circuit and a second layer of the integrated circuit. The second layer is positioned on the first layer. The transistor forms an anode and a cathode of the first capacitor. The first set of metal fingers are interdigitated with the second set of metal fingers. The first set of metal fingers and the second set of metal fingers are positioned in the second layer. The first set of metal fingers are electrically connected to the cathode of the first capacitor. The second set of metal fingers are electrically connected to the anode of the first capacitor.

According to another embodiment, an electro-optical circuit includes a substrate, a photonic integrated circuit positioned on the substrate, and an electronic integrated circuit. The electronic integrated circuit includes a first capacitor that includes a transistor and a second capacitor comprising a first set of metal fingers and a second set of metal fingers. The transistor is positioned in a first layer of the electronic integrated circuit and a second layer of the electronic integrated circuit. The second layer is positioned on the first layer. The transistor forms an anode and a cathode of the first capacitor. The first set of metal fingers are interdigitated with the second set of metal fingers. The first set of metal fingers and the second set of metal fingers are positioned in the second layer. The first set of metal fingers are electrically connected to the cathode of the first capacitor. The second set of metal fingers are electrically connected to the anode of the first capacitor.

According to another embodiment, a method includes converting, by a photonic integrated circuit, an optical signal into an electrical signal and directing, by the photonic integrated circuit, the electrical signal into an electronic integrated circuit. The electronic integrated circuit includes a first capacitor that includes a transistor and a second capacitor that includes a first set of metal fingers and a second set of metal fingers. The transistor is positioned in a first layer of the electronic integrated circuit and a second layer of the electronic integrated circuit. The second layer is positioned on the first layer. The transistor forms an anode and a cathode of the first capacitor. The first set of metal fingers are interdigitated with the second set of metal fingers. The first set of metal fingers and the second set of metal fingers are positioned in the second layer. The first set of metal fingers are electrically connected to the cathode of the first capacitor. The second set of metal fingers are electrically connected to the anode of the first capacitor.

### Example Embodiments

The present disclosure describes a unit cell that includes different types of capacitors (e.g., a metal-oxide-semiconductor capacitor (MOSCAP), a metal-oxide-metal capacitor (MOMCAP), and/or a metal-insulator-metal capacitor (MIMCAP)). The unit cell can be used in integrated circuits as a replacement for floating metal fill. In this manner, the integrated circuits contribute towards satisfying density requirements while serving as decoupling capacitors. Any number of unit cells may be positioned in the integrated circuits in any arrangement, shape, or pattern.

In certain embodiments, the unit cell provides several technical advantages. For example, the unit cell may serve the roles of a decoupling capacitor and of floating metal fill. As a result, the unit cell lessens the reliance on metal fills, which may reduce the size and cost of the integrated circuits.

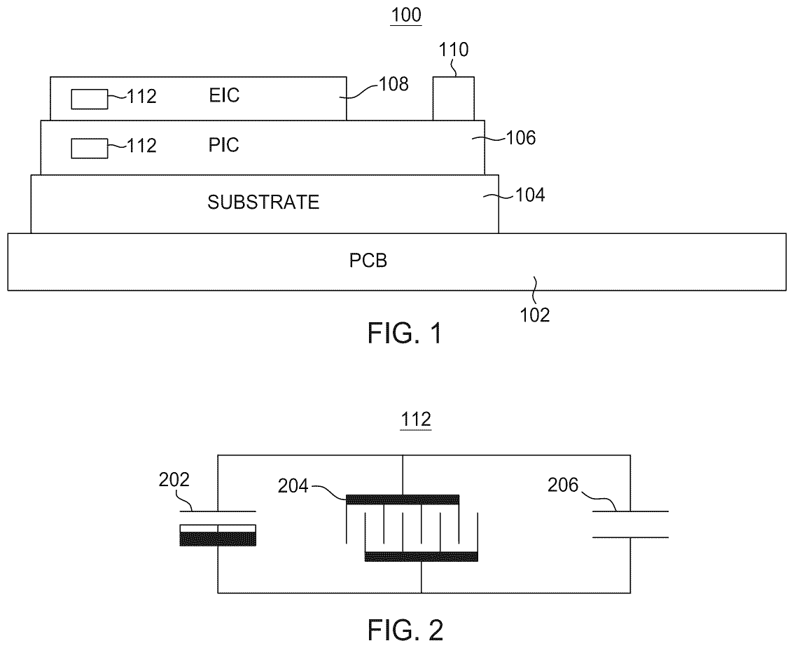

FIG. 1 illustrates an example system 100, which may be an opto-electronic circuit. As seen in FIG. 1, the system 100 includes a printed circuit board (PCB), a substrate 104, a photonic integrated circuit (PIC) 106, an electronic integrated circuit (EIC) 108, and one or more unit cells 112. Generally, the unit cells 112 may be integrated circuits that include different types of capacitors (e.g., MOSCAP, MOMCAP, MIMCAP). As a result, the unit cells 112 may be created in the electronic integrated circuit 108 and/or the photonic integrated circuit 106, and used on the PCB 102, in the PIC 106, and/or in the EIC 108 to serve as decoupling capacitors.

The PCB 102 may include an insulator layer that provides structural support for the other components of the system 100. Traces may be deposited or formed on the insulator layer. The traces electrically connect different components of the system 100. For example, the traces may electrically connect the PIC 106 and/or the EIC 108 to one or more unit cells 112 surface mounted on the PCB 102 (e.g., through vias in the substrate 104).

The substrate 104 may be a semiconductor material that provides structural support for other components of the system 100 (e.g., the PIC 106 and the EIC 108). The substrate 104 may be coupled to the PCB 102 (e.g., using solder balls). Vias may be formed in the substrate 104 to provide electrical connections to the PIC 106 and/or the EIC 108.

The PIC 106 may be formed or positioned on the substrate 104. The PIC 106 may include an optical interface 110 through which optical signals are communicated. For example, a waveguide or fiber may optically connect to the PIC 106 through the optical interface 110. The PIC 106 may convert electrical signals (e.g., from the EIC 108) into optical signals, and then the PIC 106 may communicate the optical signals through the optical interface 110. The PIC 106 may also convert optical signals (e.g., from the optical interface 110) into electrical signals. The PIC 106 may then communicate the electrical signals to the EIC 108.

The EIC 108 handles, processes, and/or analyzes electrical signals. For example, the EIC 108 may be electrically coupled to the PIC 106 (e.g., through a copper pillar and/or vias and solder balls). The EIC 108 may generate and/or communicate electrical signals to the PIC 106. The PIC 106 may convert those electrical signals to optical signals. The EIC 108 may also receive electrical signals from the PIC 106. The EIC 108 may handle, process, and/or analyze the electrical signals. The EIC 108 may then respond to the electrical signals by generating and/or communicating other electrical signals back to the PIC 106.

In existing systems, the integrated circuits (e.g., the PICs and/or EICs) may include decoupling capacitors to filter out noises at different frequencies. The integrated circuits also include floating metal fills to satisfy density requirements for reliability and manufacturability. The floating metal fill, however, is not utilized to achieve circuit functionality, and so, the floating metal fill lead to inefficient use of the area of the integrated circuits and increases the size and cost of the integrated circuits.

In the system 100, the unit cells 112 serve the purposes of the decoupling capacitors and the floating metal fill. As a result, the unit cells 112 may save design area by effectively replacing a bulk capacitor with a set of distributed capacitors that can be placed in the unused areas of the design. Additionally, the unit cells 112 may fill empty areas in the design with functional devices, which can improve thermal performance and/or reduce flatness challenges in an integrated circuit. As seen in FIG. 1, the unit cells 112 may be positioned in the PIC 106 and/or the EIC 108. Additionally, the unit cells 112 may be connected to the PCB 102. The unit cells 112 may include different types of capacitors (e.g., MOSCAP, MOMCAP, and/or MIMCAP) that serve as decoupling capacitors (e.g., when the unit cells 112 are positioned in the PIC 106 and/or EIC 108). Additionally, the unit cells 112 may be arranged in any shape or pattern to satisfy density requirements. In this manner, the unit cells 112 may provide more efficient use of the area of the PIC 106 and/or EIC 108, and the unit cells 112 may reduce the size and/or cost of the PIC 106 and/or EIC 108. Moreover, the unit cells 112 may serve as replacements of the surface mount capacitors when the unit cells 112 created in the EIC 108 and/or the PIC 106 are connected to the PCB 102. As a result, the unit cells 112 may also address capacitors needs in adjacent or external circuits by removing external discrete capacitors and instead, integrating these capacitors in to an integrated circuit design.

FIG. 2 illustrates an example unit cell 112 in the system 100 of FIG. 1. As seen in FIG. 2, the unit cell 112 may include one or more capacitors electrically connected in parallel. In the example of FIG. 2, the unit cell 112 includes a MOSCAP 202, a MOMCAP 204, and a MIMCAP 206 electrically connected in parallel to each other. In certain embodiments, the unit cell 112 may include fewer or more capacitors. For example, the unit cell 112 may include the MOSCAP 202 and the MOMCAP 204, but not the MIMCAP 206. The capacitors in the unit cell 112 serve as decoupling capacitors that filter out noises at different frequencies. As seen in subsequent figures, the MOSCAP 202, MOMCAP 204, and MIMCAP 206 may be arranged in a particular manner in the layers of an integrated circuit.

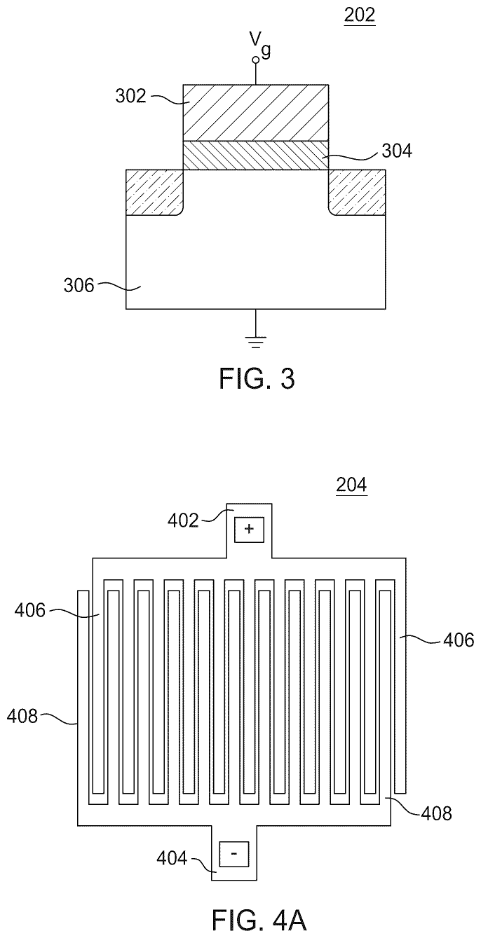

FIG. 3 illustrates an example capacitor in the unit cell 112 of FIG. 2. The capacitor in the example of FIG. 3 is the MOSCAP 202. As seen in FIG. 3, the MOSCAP 202 is formed using a transistor that includes a gate 302, an oxide layer 304 (e.g., silicon dioxide), and a body 306. Generally, the gate 302 of the transistor serves as the cathode of the MOSCAP 202, and the body 306 of the transistor serves as the anode of the MOSCAP 202. The oxide layer 304 serves as a dielectric. The capacitance of the MOSCAP 202 may depend on the voltage applied to the gate 302. In some embodiments, the body 306 of the MOSCAP 202 is formed in one layer of an integrated circuit while the gate 302 is formed in another, adjacent layer of the integrated circuit.

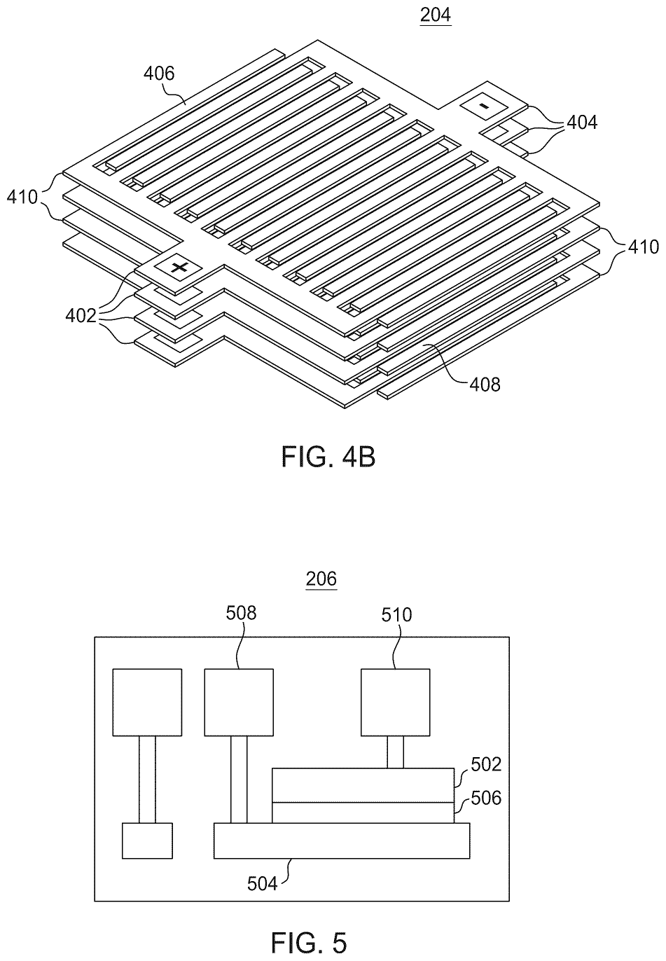

FIGS. 4A and 4B illustrate an example capacitor in the unit cell 112 of FIG. 2. The capacitor in the examples of FIGS. 4A and 4B is the MOMCAP 204. Generally, the MOMCAP 204 includes interdigitated fingers arranged in multiple layers of an integrated circuit.

FIG. 4A shows a layer of the MOMCAP 204. As seen in FIG. 4A, the layer includes a cathode 402 and an anode 404. Metal fingers 406 extend from the cathode 402 towards the anode 404. Metal fingers 408 extend from the anode 404 towards the cathode 402. The fingers 406 are interdigitated with the fingers 408. The fingers 406 and the fingers 408 may be positioned in the same layer of an integrated circuit.

FIG. 4B shows an arrangement of layers 410 of the MOMCAP 204. Generally, the MOMCAP 204 may include multiple layers 410 stacked on each other. In the example of FIG. 4B, the MOMCAP 204 includes four layers 410 stacked on each other. The layers 410 may be arranged in different layers of an integrated circuit. Each layer 410 includes a cathode 402 and an anode 404. The cathodes 402 of the layers 410 may be electrically connected to each other, and the anodes 404 of the layers 410 may be electrically connected to each other. In each layer 410, fingers 406 extend from the cathode 402 towards the anode 404, and fingers 408 extend from the anode 404 towards the cathode 402. The fingers 406 and 408 in a layer 410 may be interdigitated. In the example of FIG. 4B, the fingers 406 and 408 in adjacent layers 410 extend along the same directions. In some embodiments, the fingers 406 and 408 in adjacent layers 410 extend in different (e.g., orthogonal) directions.

FIG. 5 illustrates an example capacitor in the unit cell of FIG. 2. The capacitor in the example of FIG. 5 is the MIMCAP 206. Generally, the MIMCAP 206 uses metal in a layer of an integrated circuit to form parallel plates of the MIMCAP 206. As seen in FIG. 5, the MIMCAP 206 includes a top plate 502, a bottom plate 504, a dielectric layer 506, and metal contacts 508 and 510. The top plate 502 and bottom plate 504 may be metal plates formed using metal in the layer of the integrated circuit. The dielectric layer 506 is positioned between the top plate 502 and the bottom plate 504. The metal contacts 508 and 510 are formed using metal in the layer of the integrated circuit. The metal contacts 508 and 510 are electrically connected to the bottom plate 504 and the top plate 502. The metal contacts 508 and 510 may serve as the cathode or the anode of the MIMCAP 206.

Generally, the MOSCAP 202, MOMCAP 204, and/or MIMCAP 206 may be formed in layers of an integrated circuit. Additionally, the MOSCAP 202, MOMCAP 204, and/or MIMCAP 206 may be electrically connected in parallel with each other. For example, the cathodes of the MOSCAP 202, MOMCAP 204, and/or MIMCAP 206 may be electrically connected to each other, and the anodes of the MOSCAP 202, MOMCAP 204, and/or MIMCAP 206 may be electrically connected to each other.

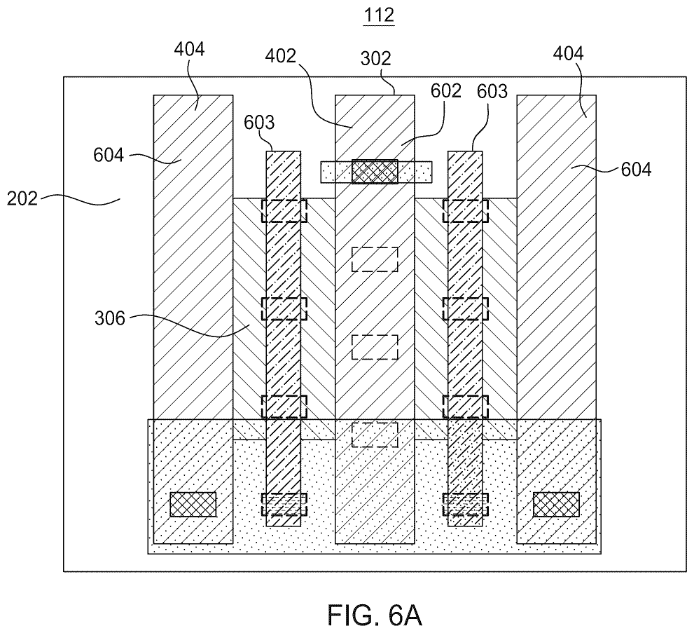

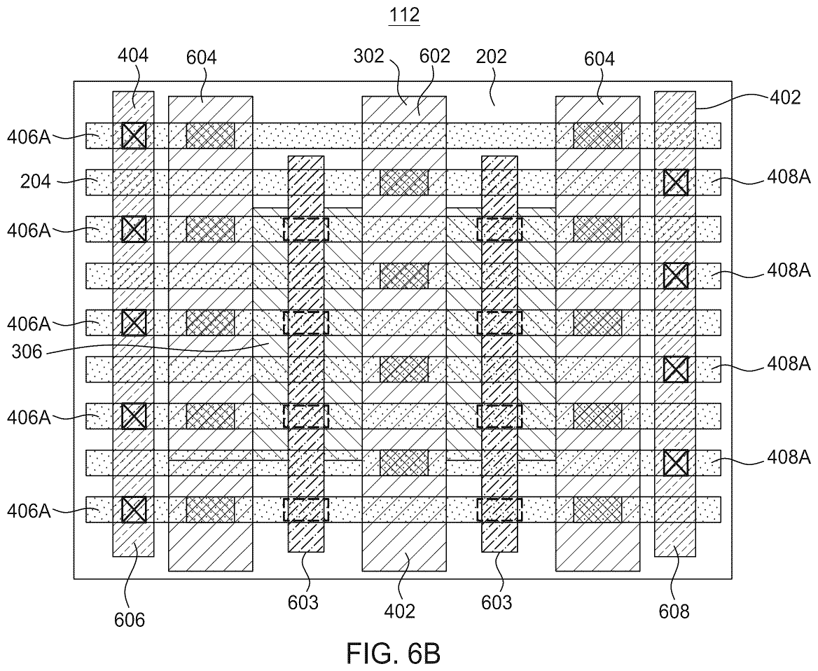

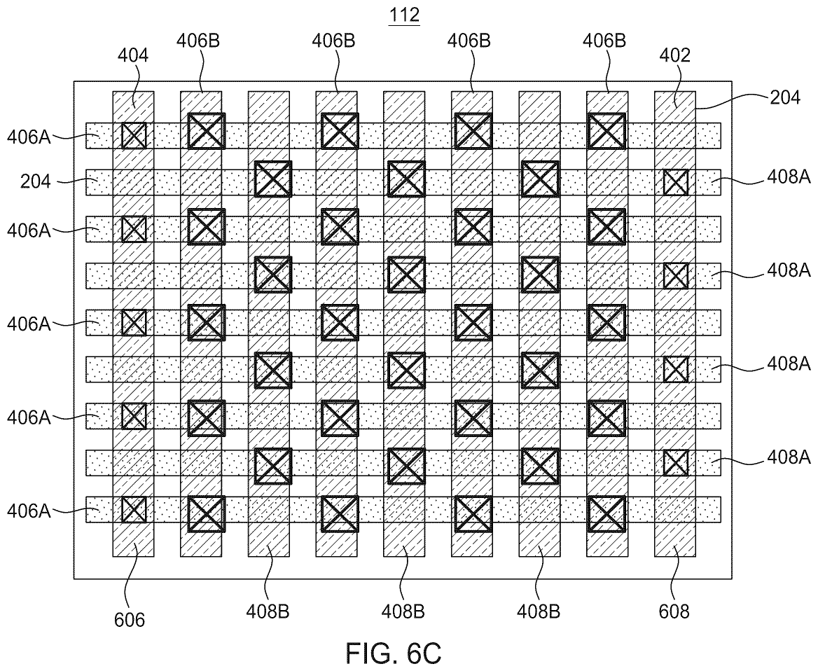

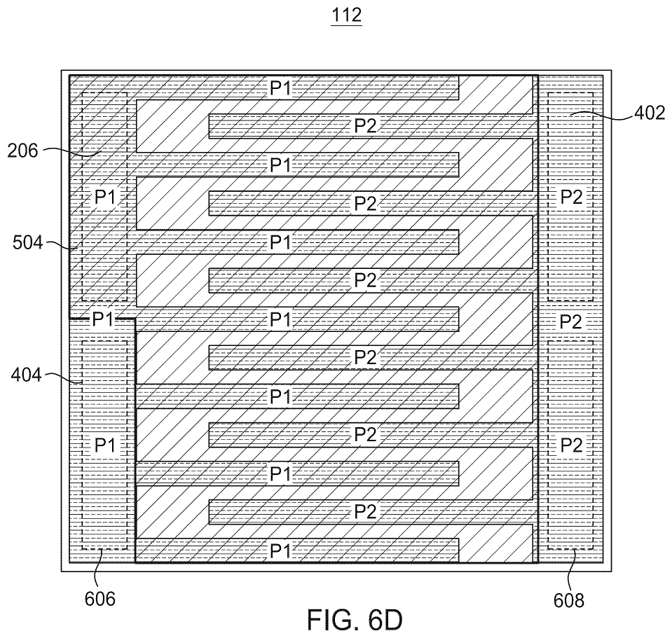

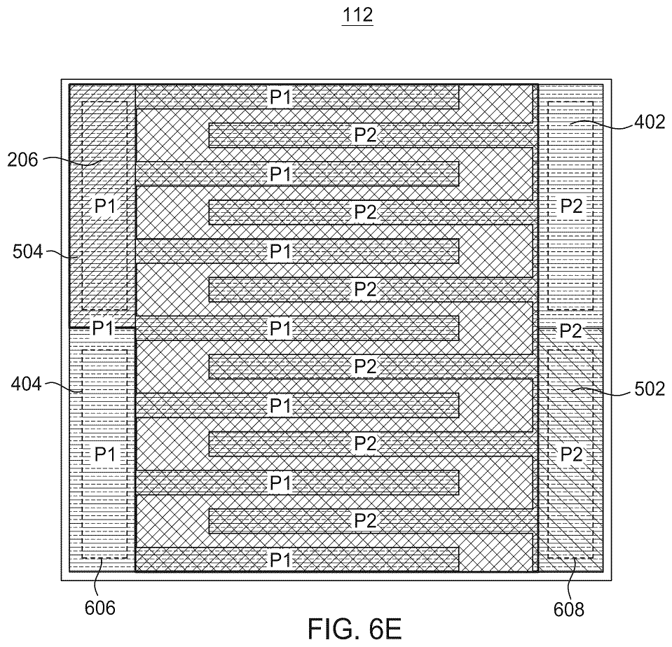

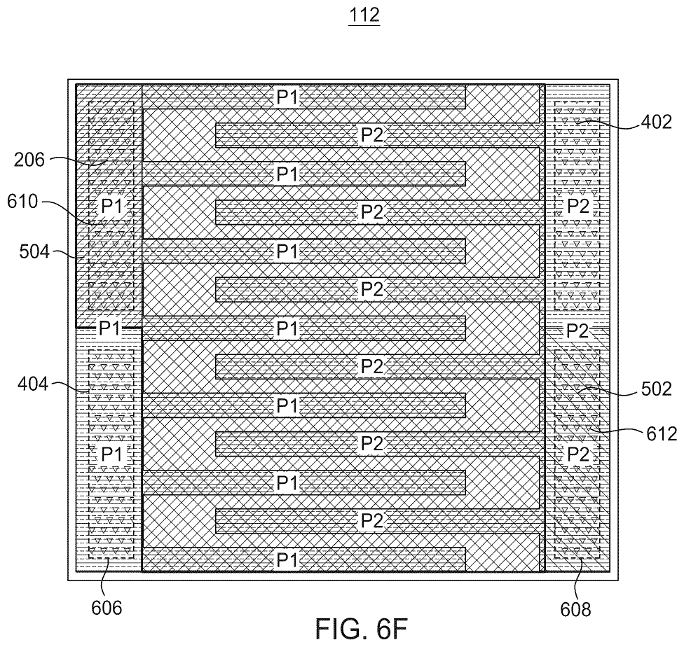

FIGS. 6A through 6F illustrate an example unit cell 112 in the system 100 of FIG. 1. Generally, FIGS. 6A through 6F show different layers of the unit cell 112. The different layers of the unit cell 112 may contain the MOSCAP 202, MOMCAP 204, and/or MIMCAP 206.

FIG. 6A shows a first layer and a second layer of the unit cell 112. The second layer may be positioned on the first layer. As seen in FIG. 6A, the MOSCAP 202 is formed in the first layer and the second layer. For example, the body 306 may be formed in the first layer while the gate 302 may be formed in the second layer above the first layer. An electrode 602 is positioned in the second layer. The electrode 602 is electrically connected to the gate 302 and serves as the cathode 402 of the MOSCAP 202. Electrodes 603 are positioned in the first layer or the second layer. The electrodes 603 are electrically connected to the body 306. Additionally, electrodes 604 are electrically connected to the electrodes 603 and serve as the anode 404 of the MOSCAP 202. In some embodiments, the second layer may be formed after the first layer. In some embodiments, the MOSCAP 202 may also have multiple electrodes 602 positioned between the electrodes 604. Each electrode 602 may be separated from another electrode 602 by an electrode 603.

FIG. 6B shows the first layer and the second layer of the unit cell 112. As seen in FIG. 6B, a layer of the MOMCAP 204 is formed in the second layer along with portions of the MOSCAP 202. The MOMCAP 204 may be formed in the second layer after the MOSCAP 202 is formed in the first and second layers. The second layer includes an electrode 606 and an electrode 608. Metal fingers 406A are electrically connected to the electrode 606 and extend towards the electrode 608. Metal fingers 408A are electrically connected to the electrode 608 and extend towards the electrode 606. The metal fingers 406A and 408A are interdigitated. The metal fingers 406A are also electrically connected to the electrodes 604, and the metal fingers 408A are also electrically connected to the electrode 602. As a result, the electrode 608 serves as the cathode 402 of the MOMCAP 204, and the cathode 402 of the MOMCAP 204 is electrically connected to the cathode 402 of the MOSCAP 202. Additionally, the electrode 606 serves as the anode 404 of the MOMCAP 204, and the anode 404 of the MOMCAP 204 is electrically connected to the anode 404 of the MOSCAP 202. In some embodiments, the MOMCAP 204 may include multiple electrodes 602 positioned between the electrodes 604. Each electrode 602 may be separated from another electrode 602 by an electrode 603.

FIG. 6C shows the second layer and a third layer of the unit cell 112. The third layer may be positioned on the second layer. As seen in FIG. 6C, a layer of the MOMCAP 204 is formed in the third layer above the fingers 406A and 408A in the second layer. The third layer includes fingers 406B and 408B that are interdigitated with each other. The fingers 406B are electrically connected (e.g., by vias) to the fingers 406A in the second layer. The fingers 408B are electrically connected (e.g., by vias) to the fingers 406B in the second layer. As a result, the fingers 406B are electrically connected to the electrode 606, which serves as the anode 404 of the MOMCAP 204, and the fingers 408B are electrically connected to the electrode 608, which serves as the cathode 402 of the MOMCAP 204. As a result portions of the MOSCAP and the MOMCAP are formed in the same layer of the integrated circuit (e.g., the second layer). In some embodiments, the third layer is formed after the first and second layers.

Additionally, the fingers 406B and 408B extend in a different direction than the fingers 406A and 408A. In the perspective shown in FIG. 6C, the fingers 406A and 408A extend laterally across the unit cell 112 (e.g., from the left side of the figure to the right side of the figure, and vice versa), and the fingers 406B and 408B extend vertically across the unit cell 112 (e.g., from the top of the figure to the bottom of the figure, and vice versa). As a result, the fingers 406B and 408B cross over the fingers 406A and 408A. In some embodiments, the fingers 406B and 408B extend in the same direction as the fingers 406A and 408A.

The MOMCAP 204 may be formed using any number of layers of the integrated circuit. Although FIGS. 6C and 6D show only two layers of the MOMCAP 204, it is understood that the MOMCAP 204 may include interdigitated fingers in more than two layers of the integrated circuit. For example, the MOMCAP 204 may be positioned in four layers of the integrated circuit. As a result, portions of the MOMCAP 204 are formed above the MOSCAP 202.

FIGS. 6D and 6E show a fourth layer of the unit cell 112 and a layer beneath the fourth layer that includes the topmost layer of the MOMCAP 204. The MIMCAP 206 is formed in the fourth layer. The fourth layer may be positioned above the MOMCAP 204 (e.g., above the topmost layer of the MOMCAP 204). As seen in FIG. 6D, a plate 504 of the MIMCAP 206 may be formed in the fourth layer. The plate 504 may be shaped such that part of the plate 504 is positioned above the electrode 606. As seen in FIG. 6E, the plate 502 is formed above the plate 504. In some embodiments, a dielectric is positioned between the plate 502 and the plate 504. The plate 502 may be shaped such that part of the plate 502 is positioned above the electrode 608. In this manner, the MIMCAP 206 is formed in the fourth layer of the unit cell 112 above the MOMCAP 204. In certain embodiments, the fourth layer is formed after the first, second, and third layers. The electrode 606 and the fingers extending from the electrode 606 are labeled ‘P1’ in FIGS. 6D and 6E. The electrode 608 and the fingers extending from the electrode 608 are labeled ‘P2’ in FIGS. 6D and 6E.

In some embodiments, the plates 502 and 504 may be formed in different layers of the unit cell 112. For example, the plate 504 may be formed in the fourth layer, and the plate 502 may be formed in a fifth layer positioned on the fourth layer. As a result, the MIMCAP 206 may span across two layers of the unit cell 112.

Although the electrodes 606 and 608 are shown as being in the layer beneath the fourth layer, it is understood that these electrodes 606 and 608 may be separate from and electrically connected to the electrodes 606 and 608 in the second layer (e.g., shown in FIG. 6B).

FIG. 6F shows the plates 502 and 504 electrically coupling to the electrodes 608 and 606. Generally, vias 610 may electrically couple the plate 504 to the electrode 606, and vias 612 may electrically couple the plate 502 to the electrode 608. There may be electrodes that electrically couple the plates 502 and 504 to the vias 612 and 610. In this manner, the plate 502 is electrically connected to the electrode 608 and to the cathode 402 of the unit cell 112. The plate 504 is electrically connected to the electrode 606 and to the anode 404 of the unit cell 112.

As seen in FIGS. 6A through 6F, the MOSCAP 202, MOMCAP 204, and MIMCAP 206 may be formed in the layers of the unit cell 112. The MOSCAP 202 may be formed in a first layer of the unit cell 112 and a second layer of the unit cell 112 positioned on the first layer. For example, the body 306 of the MOSCAP 202 may be formed in the first layer, and the gate 302 of the MOSCAP 202 may be formed in the second layer. The MOMCAP 204 may be formed in multiple layers of the unit cell 112, starting with the second layer. For example, each layer in the MOMCAP 204 may include interdigitated fingers, with some of the fingers electrically connected to the body 306 of the MOSCAP 202 and the other fingers electrically connected to the gate of the MOSCAP 202. The MIMCAP 206 may be formed in a layer of the unit cell 112 above the MOMCAP 204. The layer may include both metal plates of the MIMCAP 206. One of the metal plates is electrically connected to the body 306 of the MOSCAP 202, and the other metal plate is electrically connected to the gate 302 of the MOSCAP 202. In this manner, the MOSCAP 202, MOMCAP 204, and MIMCAP 206 are arranged in multiple layers of the unit cell 112 and are electrically connected to each other in parallel.

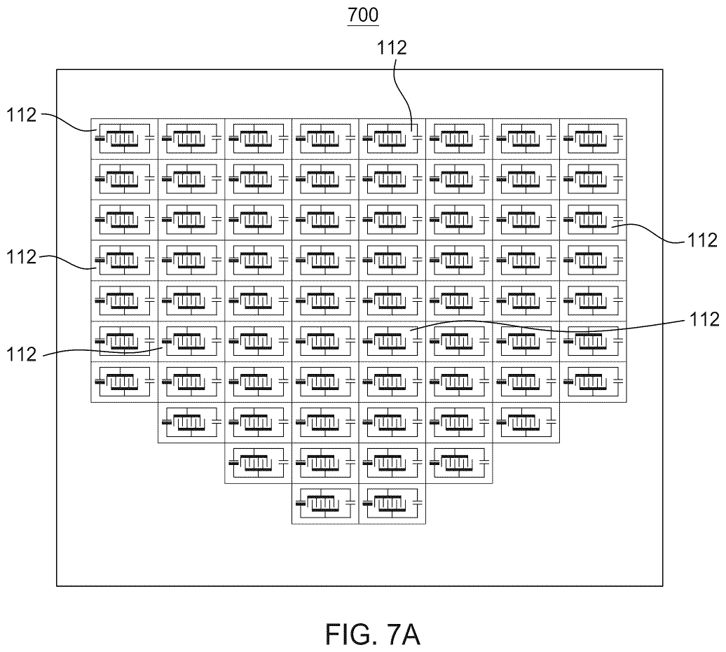

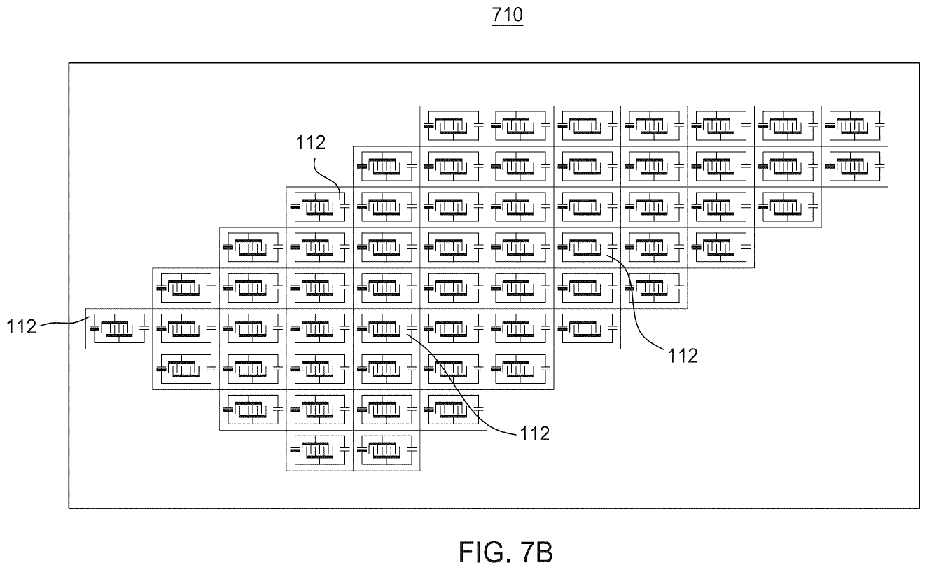

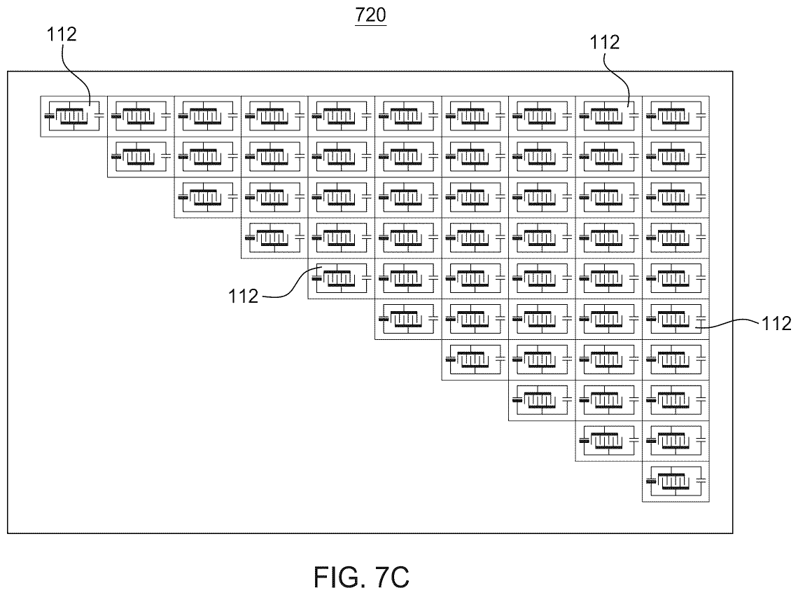

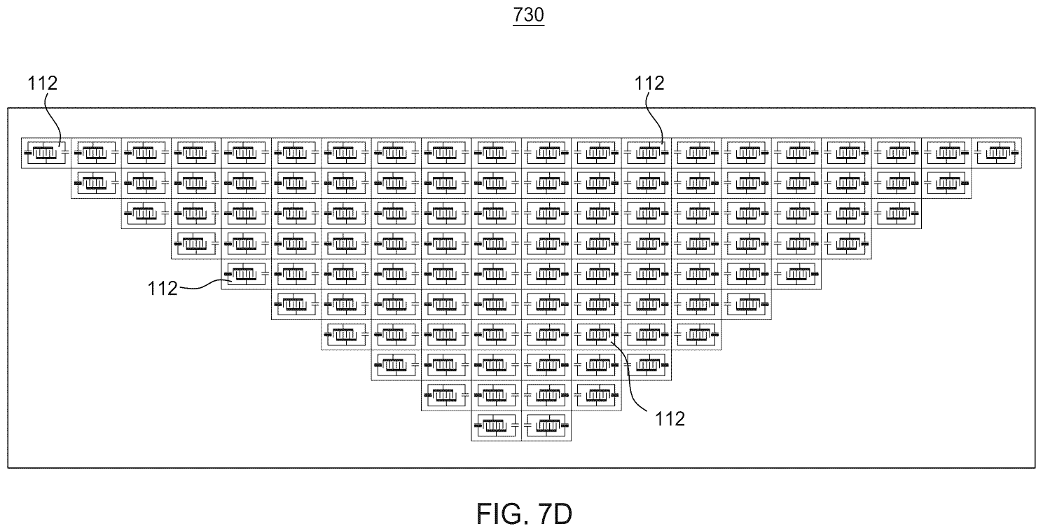

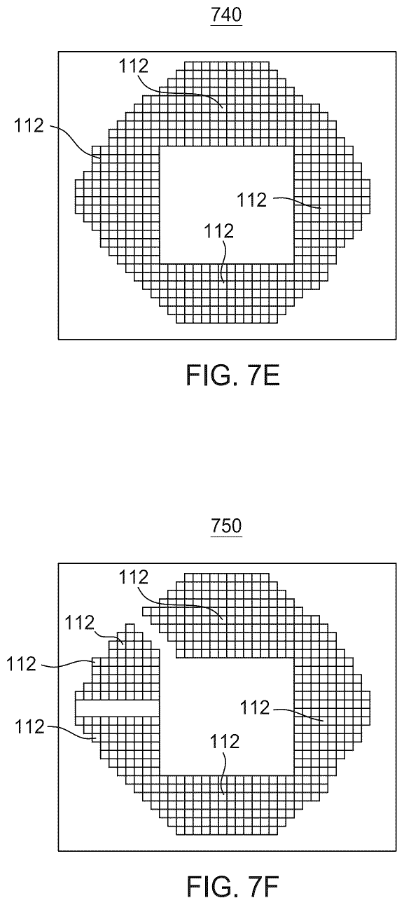

FIGS. 7A through 7F illustrate example arrangements of unit cells in the system of FIG. 1. Generally, the unit cells 112 are integrated circuits that may be positioned or arranged in other integrated circuits (e.g., the PIC 106 and/or the EIC 108). Any number of unit cells 112 may be arranged in any shape or pattern within these integrated circuits. These shapes or patterns may be designed to satisfy density requirements for reliability and manufacturability. Additionally, because the unit cells 112 include capacitors, the arrangement of unit cells 112 may also be used as decoupling capacitors. As a result, the unit cells 112 reduce the size and cost of the integrated circuits relative to integrated circuits that use both decoupling capacitors and floating metal fill, in certain embodiments. In this manner, the unit cells 112 may incrementally tile different structures to fit into complex-shaped empty spaces and/or to create capacitance. For clarity, not all of the unit cells 112 are labeled in FIGS. 7A through 7F.

FIG. 7A illustrates an arrangement 700 of multiple unit cells 112. The arrangement 700 includes the unit cells 112 arranged in a symmetrical shape. FIG. 7B illustrates an arrangement 710 of multiple unit cells. The arrangement 710 includes the unit cells 112 arranged in a generally diagonal shape. FIG. 7C illustrates an arrangement 720 of multiple unit cells 112. The arrangement 720 includes the unit cells 112 arranged in a triangular shape. FIG. 7D illustrates an arrangement 730 of multiple unit cells. The arrangement 730 includes the unit cells 112 arranged in a triangular shape. FIG. 7E illustrates an arrangement 740 of multiple unit cells 112. The arrangement 740 includes the unit cells 112 arranged in a ring shape. FIG. 7F illustrates an arrangement 750 of multiple unit cells 112. The arrangement 750 includes the unit cells 112 arranged in the shape of a broken or segmented ring.

As seen in FIGS. 7A through 7F, the unit cells 112 may be arranged in any shape or pattern. As a result, the unit cells 112 may be used to fill areas of an integrated circuit (e.g., the PIC 106 or EIC 108) of any shape or size. As a result, the unit cells 112 may be arranged to serve both the functions of decoupling capacitors and floating metal fill, which reduces the size and cost of the integrated circuit, in certain embodiments.

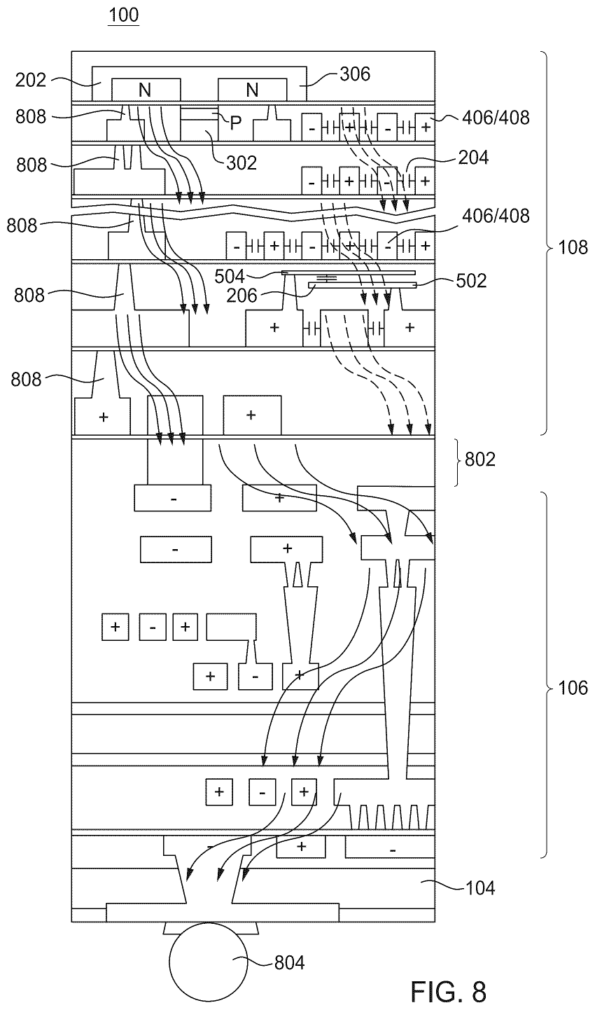

FIG. 8 illustrates portions of the system 100 of FIG. 1. As seen in FIG. 8, the system 100 includes the PIC 106 and the EIC 108. The EIC 108 is positioned above the PIC 106 and is electrically connected to the PIC 106 by a pillar 802 (e.g., a copper pillar). The EIC 108 has been flipped so that the top of the EIC 108 is directed towards the PIC 106 and the bottom of the EIC 108 is directed away from the PIC 106.

As seen in FIG. 8, the EIC 108 includes the MOSCAP 202. The body 306 of the MOSCAP 202 is positioned in a first layer of the EIC 108, and the gate 302 of the MOSCAP 202 is positioned in an adjacent, second layer of the EIC 108. Interdigitated fingers 406 and 408 of the MOMCAP 204 are also positioned in the second layer of the EIC 108. The fingers 406 and 408 are also positioned in subsequent, third and fourth layers of the EIC 108. The plates 502 and 504 of the MIMCAP 206 are positioned in a fifth layer of the EIC 108 adjacent to the fourth layer. As a result, the MOSCAP 202, MOMCAP 204, and MIMCAP 206 are generally positioned in stacked layers of the EIC 108.

The pillar 802 provides an electrical connection between the EIC 108 and the PIC 106. The EIC 108 and the PIC 106 may communicate electrical signals to each other through the copper pillar 802. Additionally, the PIC 106 is positioned on the substrate 104. A via extends through the substrate 104 to form an electrical connection with a solder ball 804.

In some embodiments, vias 808 are positioned in the layers of the EIC 108. The vias 808 form electrical and/or thermal conduction pathways through the layers of the EIC 108. As a result, the vias 808 connect the metal layers of the EIC 108, and the vias 808 improve the thermal conduction through the metal layers of the EIC 108. In the example of FIG. 8, the vias 808 are connected to the cathode and the anode of the capacitors (e.g., the MOSCAP 202, the MOMCAP 204, and the MIMCAP 206). The vias 808 transfer heat away from the anode and cathode of the capacitors.

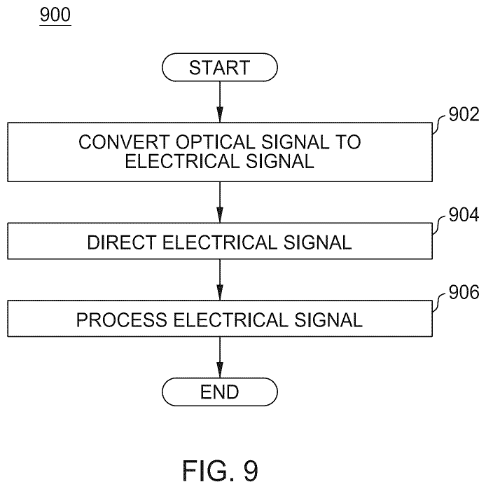

FIG. 9 is a flowchart of an example method 900 performed by the system 100 of FIG. 1. Generally, various components of the system 100 perform the steps of the method 900. By performing the method 900, the system 100 may communicate optical and electrical signals while reducing the size and cost of an integrated circuit.

In block 902, the PIC 106 converts an optical signal to an electrical signal. The PIC 106 may have received the optical signal through the optical interface 110. In block 904, the PIC 106 directs the electrical signal to the EIC 108. For example, the PIC 106 may direct the electrical signal through the pillar 802 and into the EIC 108.

In block 906, the EIC 108 processes the electrical signal. The EIC 108 may include areas that are occupied by the unit cells 112. The unit cells 112 may include different capacitors (e.g., MOSCAP 202, MOMCAP 204, MIMCAP 206) that serve as decoupling capacitors for the EIC 108. Additionally, the unit cells 112 may also be arranged to serve the function of floating metal fill.

In summary, the unit cell 112 includes different types of capacitors and can be used in integrated circuits as a replacement for floating metal fill. In this manner, the unit cell 112 contributes towards satisfying density requirements while serving as decoupling capacitors. Any number of unit cells 112 may be positioned in the integrated circuits in any arrangement, shape, or pattern.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

In view of the foregoing, the scope of the present disclosure is determined by the claims that follow.

We claim:

1. An integrated circuit comprising:
a first capacitor comprising a transistor, wherein the transistor is positioned in a first layer of the integrated circuit and a second layer of the integrated circuit, wherein the second layer is positioned on the first layer, and wherein the transistor forms an anode and a cathode of the first capacitor; and
a second capacitor comprising a first set of metal fingers and a second set of metal fingers, wherein the first set of metal fingers are interdigitated with the second set of metal fingers, wherein the first set of metal fingers and the second set of metal fingers are positioned in the second layer, wherein the first set of metal fingers are electrically connected to the cathode of the first capacitor, and wherein the second set of metal fingers are electrically connected to the anode of the first capacitor.

2. The integrated circuit of claim 1, wherein the second capacitor further comprises a third set of metal fingers and a fourth set of metal fingers interdigitated with the third set of metal fingers, wherein the third set of metal fingers and the fourth set of metal fingers are positioned in a third layer of the integrated circuit, wherein the third layer is positioned on the second layer, and wherein the third set of metal fingers are electrically connected to the cathode of the first capacitor, and wherein the fourth set of metal fingers are electrically connected to the anode of the first capacitor.

3. The integrated circuit of claim 2, wherein a metal finger of the third set of metal fingers is positioned such that the metal finger of the third set of metal fingers crosses over metal fingers of the first set of metal fingers and metal fingers of the second set of metal fingers.

4. The integrated circuit of claim 1, further comprising a third capacitor comprising a first metal layer and a second metal layer, wherein the first metal layer and the second metal layer are positioned in a third layer of the integrated circuit different from the first layer and the second layer, and wherein the first metal layer is electrically connected to the cathode of the first capacitor, and wherein the second metal layer is connected to the anode of the first capacitor.

5. The integrated circuit of claim 4, wherein the third capacitor further comprises a dielectric positioned between the first metal layer and the second metal layer.

6. The integrated circuit of claim 1, wherein the cathode and the anode of the first capacitor are connected to a via, wherein the via is arranged to transfer heat away from the cathode and the anode.

7. The integrated circuit of claim 1, further comprising a photonic integrated circuit, wherein the integrated circuit is an electronic integrated circuit, and wherein the electronic integrated circuit is positioned on the photonic integrated circuit.

8. The integrated circuit of claim 1, wherein the integrated circuit is a photonic integrated circuit.

9. The integrated circuit of claim 1, further comprising a printed circuit board, wherein the integrated circuit is mounted directly on the printed circuit board.

10. An electro-optical circuit comprising:
a substrate;
a photonic integrated circuit positioned on the substrate; and
an electronic integrated circuit, wherein the electronic integrated circuit comprises:
a first capacitor comprising a transistor, wherein the transistor is positioned in a first layer of the electronic integrated circuit and a second layer of the electronic integrated circuit, wherein the second layer is positioned on the first layer, and wherein the transistor forms an anode and a cathode of the first capacitor; and
a second capacitor comprising a first set of metal fingers and a second set of metal fingers, wherein the first set of metal fingers are interdigitated with the second set of metal fingers, wherein the first set of metal fingers and the second set of metal fingers are positioned in the second layer, wherein the first set of metal fingers are electrically connected to the cathode of the first capacitor, and wherein the second set of metal fingers are electrically connected to the anode of the first capacitor.

11. The electro-optical circuit of claim 10, wherein the second capacitor further comprises a third set of metal fingers and a fourth set of metal fingers interdigitated with the third set of metal fingers, wherein the third set of metal fingers and the fourth set of metal fingers are positioned in a third layer of the electronic integrated circuit, wherein the third layer is positioned on the second layer, and wherein the third set of metal fingers are electrically connected to the cathode of the first capacitor, and wherein the fourth set of metal fingers are electrically connected to the anode of the first capacitor.

12. The electro-optical circuit of claim 11, wherein a metal finger of the third set of metal fingers is positioned such that the metal finger of the third set of metal fingers crosses over metal fingers of the first set of metal fingers and metal fingers of the second set of metal fingers.

13. The electro-optical circuit of claim 10, wherein the electronic integrated circuit further comprises a third capacitor comprising a first metal layer and a second metal layer, wherein the first metal layer and the second metal layer are positioned in a third layer of the electronic integrated circuit different from the first layer and the second layer, and wherein the first metal layer is electrically connected to the cathode of the first capacitor, and wherein the second metal layer is connected to the anode of the first capacitor.

14. The electro-optical circuit of claim 13, wherein the third capacitor further comprises a dielectric positioned between the first metal layer and the second metal layer.

15. The electro-optical circuit of claim 10, wherein the cathode and the anode of the first capacitor are connected to a via, wherein the via is arranged to transfer heat away from the cathode and the anode.

16. A method comprising:
converting, by a photonic integrated circuit, an optical signal into an electrical signal; and
directing, by the photonic integrated circuit, the electrical signal into an electronic integrated circuit, wherein the electronic integrated circuit comprises:
a first capacitor comprising a transistor, wherein the transistor is positioned in a first layer of the electronic integrated circuit and a second layer of the electronic integrated circuit, wherein the second layer is positioned on the first layer, and wherein the transistor forms an anode and a cathode of the first capacitor; and
a second capacitor comprising a first set of metal fingers and a second set of metal fingers, wherein the first set of metal fingers are interdigitated with the second set of metal fingers, wherein the first set of metal fingers and the second set of metal fingers are positioned in the second layer, wherein the first set of metal fingers are electrically connected to the cathode of the first capacitor, and wherein the second set of metal fingers are electrically connected to the anode of the first capacitor.

17. The method of claim 16, wherein the second capacitor further comprises a third set of metal fingers and a fourth set of metal fingers interdigitated with the third set of metal fingers, wherein the third set of metal fingers and the fourth set of metal fingers are positioned in a third layer of the electronic integrated circuit, wherein the third layer is positioned on the second layer, and wherein the third set of metal fingers are electrically connected to the cathode of the first capacitor, and wherein the fourth set of metal fingers are electrically connected to the anode of the first capacitor.

18. The method of claim 17, wherein a metal finger of the third set of metal fingers is positioned such that the metal finger of the third set of metal fingers crosses over metal fingers of the first set of metal fingers and metal fingers of the second set of metal fingers.

19. The method of claim 16, wherein the electronic integrated circuit further comprises a third capacitor comprising a first metal layer and a second metal layer, wherein the first metal layer and the second metal layer are positioned in a third layer of the electronic integrated circuit different from the first layer and the second layer, and wherein the first metal layer is electrically connected to the cathode of the first capacitor, and wherein the second metal layer is connected to the anode of the first capacitor.

20. The method of claim 19, wherein the third capacitor further comprises a dielectric positioned between the first metal layer and the second metal layer.
